(19) United States
(12) Patent Application Publication
(10) Pub. No.: US 2020/0110681 A1
(43) Pub. Date: Apr. 9, 2020

(54) CENTRALIZED CONTROL IN A DISTRIBUTED STIMULUS-BASED TEST-BENCH ENVIRONMENT

(71) Applicant: International Business Machines Corporation, Armonk, NY (US)

(72) Inventors: Akash Giri, Austin, TX (US); Gaurav Sulagodu Venkatagiri, Bangalore (IN)

(21) Appl. No.: 16/150,739

(22) Filed: Oct. 3, 2018

(51) Int. Cl. G06F 11/26; G06F 11/34; G06F 17/50; G06F 15/18

(52) U.S. Cl. CPC G06F 11/261; G06F 11/3428; G01R 31/2879; G06F 17/504; G06F 15/18; G06F 17/5022

(57) ABSTRACT

Aspects include receiving, at a central controller, a stimulation request from a first autonomous test bench of a plurality of autonomous test benches configured to stimulate a device under test that is a functional unit of a microprocessor. A set of conditions is accessed based on one or more states of the device under test and the autonomous test benches, the set of conditions mapping to a stimulation event type. A set of programmable controls is accessed based on collating past behavior of the autonomous test benches to determine a stimulation pattern for the autonomous test benches and a plurality of stimulation event types. The central controller provides a response to the first autonomous test bench indicating whether the first autonomous test bench is authorized to drive the device under test with the stimulation event type based on the set of conditions and the set of programmable controls.

### BACKGROUND

The present invention relates to computer systems, and more particularly, to centralized control in a distributed stimulus-based test-bench environment for testing computer system component designs.

High performance microprocessor designs generally include several separate but interconnected functional blocks or units. In order to account for design complexity, functional verification environments often utilize a constrained random approach. In this approach, test bench components are developed on a functional unit basis to stimulate various input interfaces into the functional unit. Since a given unit may have input interfaces from several other separate units, the input interface stimulus components are developed separately such that a set of distributed components is formed, which together stimulate all the input interfaces of the unit.

### SUMMARY

According to one or more embodiments of the present invention, a computer-implemented method includes receiving, at a central controller, a stimulation request from a first autonomous test bench of a plurality of autonomous test benches configured to stimulate a device under test that is a functional unit of a microprocessor. A set of conditions is accessed based on one or more states of the device under test and the autonomous test benches, the set of conditions mapping to a stimulation event type. A set of programmable controls is accessed based on collating past behavior of the autonomous test benches to determine a stimulation pattern for the autonomous test benches and a plurality of stimulation event types. The central controller provides a response to the first autonomous test bench indicating whether the first autonomous test bench is authorized to drive the device under test with the stimulation event type based on the set of conditions and the set of programmable controls.

Other embodiments of the invention implement the features of the above-described method in a computer system and in a computer program product.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a block diagram illustrating a computer system in accordance with various embodiments of the invention;

FIG. 2 is a block diagram of functional units of a microprocessor device under test according to a non-limiting embodiment;

FIG. 3 is a block diagram of a test bench environment according to a non-limiting embodiment;

FIG. 4 is a block diagram of inputs to a test bench environment according to a non-limiting embodiment;

FIG. 5 is a block diagram of inputs and outputs to a test bench environment according to a non-limiting embodiment;

FIG. 6 is a flow diagram illustrating a method according to a non-limiting embodiment; and

FIG. 7 is a flow diagram illustrating a method according to a non-limiting embodiment.

The diagrams depicted herein are illustrative. There can be many variations to the diagrams or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can include any integer number greater than or equal to one, i.e. one, two, three, four, etc. The terms “a plurality” can include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

For the sake of brevity, conventional techniques related to making and using aspects of the invention may or may not be described in detail herein. In particular various aspects of computing systems and specific computer programs to implement the various technical features described herein are well known. Accordingly, in the interest of brevity, many conventional implementation details are only mentioned briefly herein or are omitted entirely without providing the well-known system and/or process details.

Turning now to an overview of technologies that are more specifically relevant to aspects of the invention, multiple autonomous test benches can be used to stimulate a device under test, such as a functional unit of a microprocessor. The autonomous test benches are typically implemented independently to isolate complexity and more readily adhere to interface specifications of the device under test. The autonomous test benches can be implemented in parallel to allow for more expeditious development schedules. Although this approach provides for both efficient and extensive functional coverage, it may not provide precise control over the input stimulus in a coordinated fashion. Lack of coordination may result in extended testing times, for instance, where one of the autonomous test benches interferes with an on-going test being run by another autonomous test bench.

Turning now to an overview of the aspects of the invention, one or more embodiments of the invention address the above-described shortcomings of the prior art by incorporating a central controller to coordinate actions of a plurality of autonomous test benches configured to stimulate a device under test. Each autonomous test bench is cognizant of conditions that determine if stimulation is viable based on a set of interface specification rules. This is referred to herein as ‘Can I Drive’ logic that can include one or more equations. The central controller can perform handshaking with the individual autonomous test benches. Handshaking can be performed by the autonomous test benches querying the central controller to determine whether an event should be stimulated, which is referred to herein as ‘Should I Drive’ logic that can include one or more equations.

The above-described aspects of the invention address the shortcomings of the prior art by using a two-tiered approach to stimulating events in combination with handshaking through the central controller. Each autonomous test bench can use an encapsulation of an event to be stimulated. The encapsulation is referred to as a ‘stimulation event type’ or ‘StimulationEventType’, where a StimulationEventType can be categorized as either a specific type and/or a generic type of stimulation event. For example, a StimulationEventType can be implemented to encapsulate a unique signal on a device under test interface. A generic StimulationEventType can be implemented to encapsulate a set of specific StimulationEventTypes which are inter-related based on underlying functionality. An autonomous test bench can be cognizant of specific StimulationEventTypes, whereas the central controller can be cognizant of both specific and generic StimulationEventTypes and utilizes the latter category to control the former. Technical effects and benefits can include improved test coverage by providing more precise control over input stimulus in a coordinated fashion for functional testing of a microprocessor design.

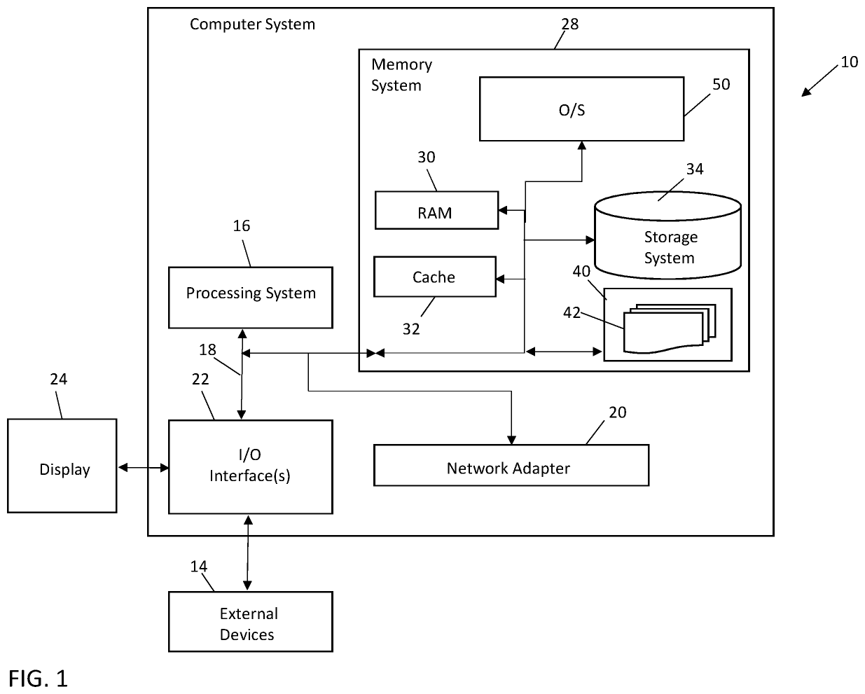

With reference now to FIG. 1, a computer system 10 is illustrated in accordance with a non-limiting embodiment of the present disclosure. The computer system 10 may be based on the z/Architecture, for example, offered by International Business Machines Corporation (IBM). The architecture, however, is only one example of the computer system 10 and is not intended to suggest any limitation as to the scope of use or functionality of embodiments described herein. Regardless, computer system 10 is capable of being implemented and/or performing any of the functionality set forth hereinabove.

Computer system 10 is operational with numerous other computing system environments or configurations. Examples of well-known computing systems, environments, and/or configurations that may be suitable for use with computer system 10 include, but are not limited to, personal computer systems, server computer systems, thin clients, thick clients, cellular telephones, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like. Further, elements of the computer system 10 can be incorporated in one or more network devices to support computer network functionality, such as a network switch, a network router, or other such network support devices.

Computer system 10 may be described in the general context of computer system-executable instructions, such as program modules, being executed by the computer system 10. Generally, program modules may include routines, programs, objects, components, logic, data structures, and so on that perform particular tasks or implement particular abstract data types. Computer system 10 may be practiced in distributed cloud computing environments where tasks are performed by remote processing devices that are linked through a communications network. In a distributed computing environment, program modules may be located in both local and remote computer system storage media including memory storage devices.

As shown in FIG. 1, computer system 10 is shown in the form of a computing device, also referred to as a processing device. The components of computer system may include, but are not limited to, a processing system 16 including one or more processors or processing units, a memory system 28, and a bus 18 that operably couples various system components including memory system 28 to processing system 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system 10 may include a variety of computer system readable media. Such media may be any available media that are accessible by computer system/server 10, and they include both volatile and non-volatile media, removable and non-removable media.

Memory system 28 can include an operating system (OS) 50, along with computer system readable media in the form of volatile memory, such as random access memory (RAM) 30 and/or cache memory 32. Computer system 10 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory system 28 may include at least one program product having a set (e.g., at least one) of program modules that are configured to carry out the functions of embodiments of the disclosure.

The OS 50 controls the execution of other computer programs and provides scheduling, input-output control, file and data management, memory management, and communication control and related services. The OS 50 can also include communication protocol support as one or more drivers to implement various protocol layers in a protocol stack (e.g., transmission control protocol/internet protocol (TCP/IP)) to support communication with other computer systems across one or more computer networks.

The storage system 34 can store a basic input output system (BIOS). The BIOS is a set of essential routines that initialize and test hardware at startup, start execution of the OS 50, and support the transfer of data among the hardware devices. When the computer system 10 is in operation, the processing system 16 is configured to execute instructions stored within the storage system 34, to communicate data to and from the memory system 28, and to generally control operations of the computer system 10 pursuant to the instructions.

Program/utility 40, having a set (at least one) of program modules 42, may be stored in memory system 28 by way of example, and not limitation, as well as the OS 50, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein at an application layer level in a communication protocol stack.

Computer system 10 may also communicate with one or more external devices 14 such as a keyboard, a pointing device, a display 24, etc.; one or more devices that enable a user to interact with computer system/server 10; and/or any devices (e.g., network card, modem, etc.) that enable computer system/server 10 to communicate with one or more other computing devices. Such communication can occur via Input/Output (I/O) interfaces 22. Still yet, computer system 10 can communicate with one or more networks such as a local area network (LAN), a general wide area network (WAN), and/or a public network (e.g., the Internet) via network adapter 20. As depicted, network adapter 20 communicates with the other components of computer system 10 via bus 18. It should be understood that although not shown, other hardware and/or software components could be used in conjunction with computer system 10. Examples include, but are not limited to: microcode, device drivers, redundant processing units, external disk drive arrays, RAID systems, tape drives, data archival storage systems, etc.

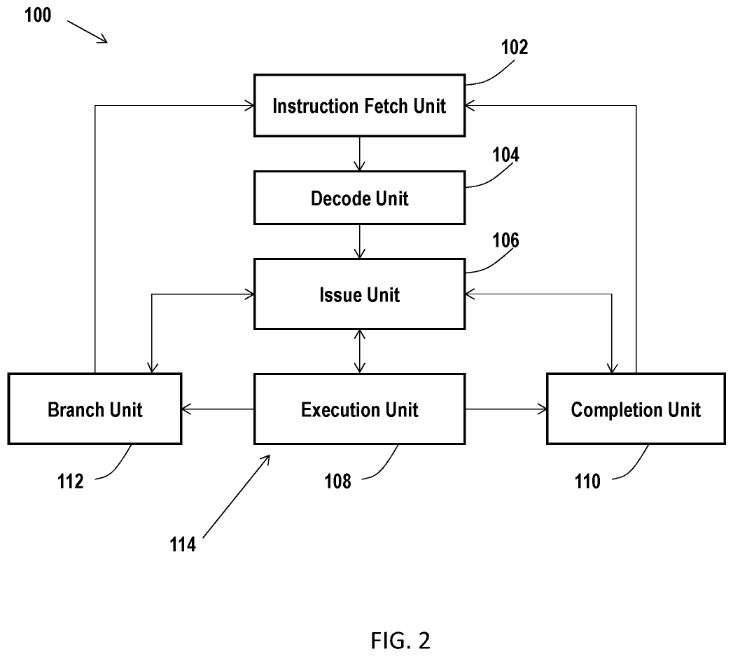

Turning now to a more detailed description of aspects of the present invention, FIG. 2 depicts a block diagram of a portion of a microprocessor 100 that can be part of the processing system 16 of FIG. 1. The microprocessor 100 can include a plurality of functional units, such as an instruction fetch unit 102, a decode unit 104, an issue unit 106, an execution unit 108, a completion unit 110, and branch unit 112. The instruction fetch unit 102, decode unit 104, issue unit 106, execution unit 108, completion unit 110, and/or other units of the microprocessor 100 not depicted in FIG. 2 may each have one or more pipelines with multiple stages. After instruction decoding by the decode unit 104, the issue unit 106 can route and sequence instructions to the execution unit 108, completion unit 110, and/or branch unit 112. A stuck state value may exist within a pipeline of the instruction fetch unit 102, decode unit 104, issue unit 106, execution unit 108, completion unit 110, and/or other units of the microprocessor 100 not depicted in FIG. 2, for instance, due to an error condition. The stuck state value can lead to errant results upon a subsequent test of the unit 102-112 in which the stuck state value resides. Various inputs to units 102-112 (also referred to as functional units 102-112) can establish a state for normal operations, while other stimulus may be available for events such as a flush reset to clear state values and/or initiate a retry of a set of instructions by reverting to an earlier point in an instruction stream.

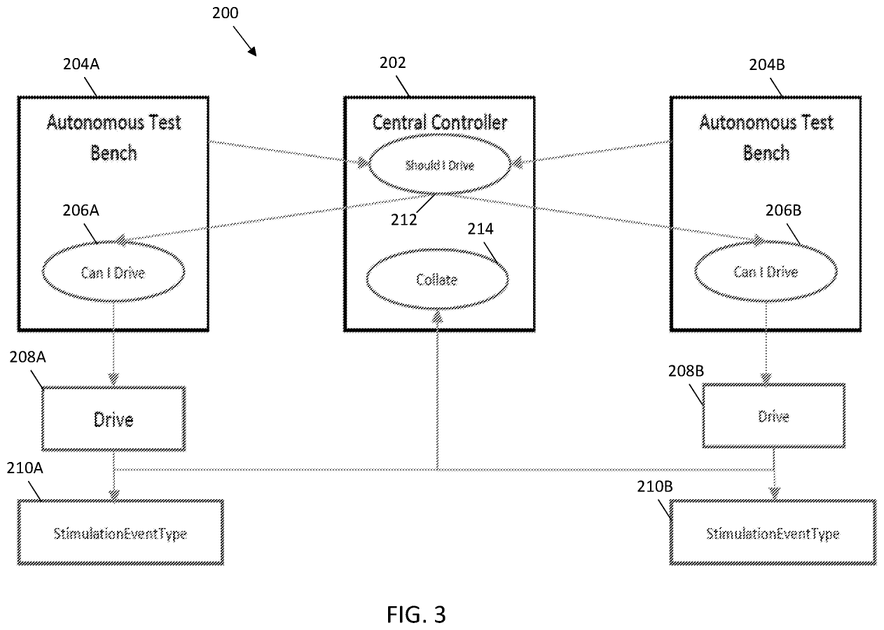

Although only six functional units 102-112 are depicted in the example of FIG. 2, it will be understood that any number of functional units 102-112 can be incorporated in the microprocessor 100. Further, functional units 102-112 can be comprised of a plurality of subunits. For example, the execution unit 108 may include one or more fixed-point execution units, floating-point execution units, load/store execution units, and/or vector execution units. As can be seen in the example of FIG. 2, some functional units 102-112, such as the instruction fetch unit 102, issue unit 106, completion unit 110, and branch unit 112, can interface with multiple functional units 102-112 and may receive multiple inputs. Any of the functional units 102-112 can be designated as a device under test (DUT) 114 for testing the underlying design using one or more autonomous test benches as further described in reference to FIGS. 3-5.

FIGS. 3-5 depict example test bench environments 200, 300, and 400 for testing one or more DUTs 114 of FIG. 2. Test bench environment 200 includes a central controller 202, a first autonomous test bench 204A, and a second autonomous test bench 204B. The first autonomous test bench 204A includes ‘Can I Drive’ logic 206A configured to interface with a drive 208A operable to produce a StimulationEventType 210A for the DUT 114 of FIG. 2. Similarly, the second autonomous test bench 204B includes ‘Can I Drive’ logic 206B configured to interface with a drive 208B operable to produce a StimulationEventType 210B for the DUT 114. To reduce resource contention and interference between autonomous actions by the first and second autonomous test benches 204A, 204B, each of the first and second autonomous test benches 204A, 204B can interface with ‘Should I Drive’ logic 212 of the central controller 202 and collate logic 214 to manage stimulation patterns and sequencing with respect to the DUT 114.

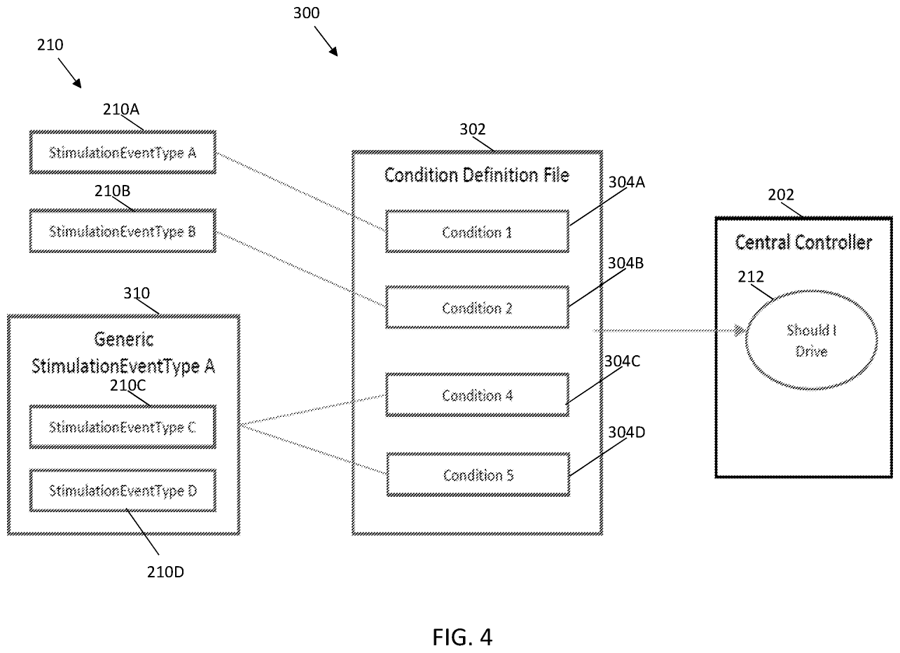

The ‘Should I Drive’ logic 212 can make use of two or more resources. A first resource can be a set of conditions based on one or more states of the DUT 114 and/or the first and second autonomous test benches 204A, 204B. The second resource can be a set of programmable controls based on collating past stimulation behavior of a plurality of autonomous test benches 204. The methodology can be expanded to incorporate more than two resources to determine the results of the ‘Should I Drive’ logic 212. The first resource, which is a set of conditions based on the state of the DUT 114 and/or autonomous test benches 204, may be a shared resource referred to herein as a Condition Definition File (CDF) 302. The CDF 302 can serve to correlate a condition or set of conditions, such as conditions 304A, 304B, 304C, 304D with a plurality of StimulationEventTypes 210, either specific or generic. In the example of FIG. 4, condition 304A maps to StimulationEventTypeA 210A, condition 304B maps to StimulationEventTypeB 210B, condition 304C maps to StimulationEventTypeC 210C, and condition 304D maps to StimulationEventTypeD 210D. StimulationEventTypeA 210A, StimulationEventTypeB 210B, StimulationEventTypeC 210C, and StimulationEventTypeD 210D are examples of specific stimulation event types, and StimulationEventTypeC 210C and StimulationEventTypeD 210D can be encapsulated as a Generic StimulationEventType 310.

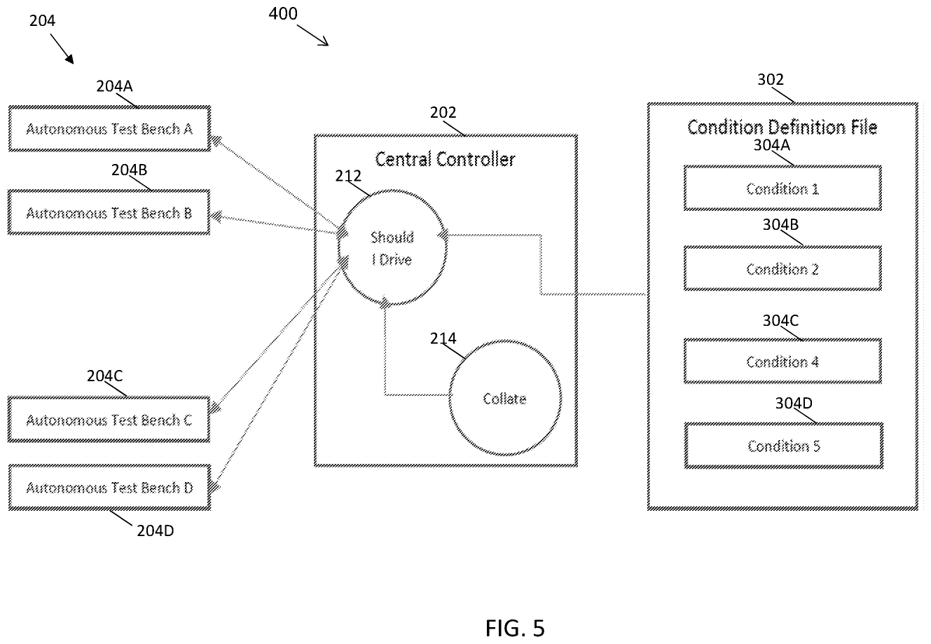

As depicted in the example of FIG. 5, any number of autonomous test benches 204 can interface with the ‘Should I Drive’ logic 212, such as a first autonomous test bench 204A, a second autonomous test bench 204B, a third autonomous test bench 204C, and a fourth autonomous test bench 204D.

As a further example, an embodiment of a condition based on a hardware state of the DUT 114, referred to as ‘HwConditionA’, can be the availability of a DUT 114 resource, such as the number of valid entries in a specific buffer. An exemplary embodiment of a condition based on test bench state of the autonomous test benches 204, referred to as ‘TbConditionA’, is quiescence of a StimulationEventType 210 (either specific or generic) based on the current position in the simulation timeline. With respect to the second resource, which can be a set of programmable controls based on collating past behavior of one or more autonomous test benches 204, the collate logic 214 of the central controller 202 can incorporate collated data to control StimulationEventTypes 210 (either specific or generic). The collate logic 214 may be configurable and can enable defining desired patterns in how the autonomous test benches 204 stimulate events. For instance, the programmable controls can define a valid sequence of stimulation event types 210 and/or a valid sequence of interactions with respect to two or more of the autonomous test benches 204.

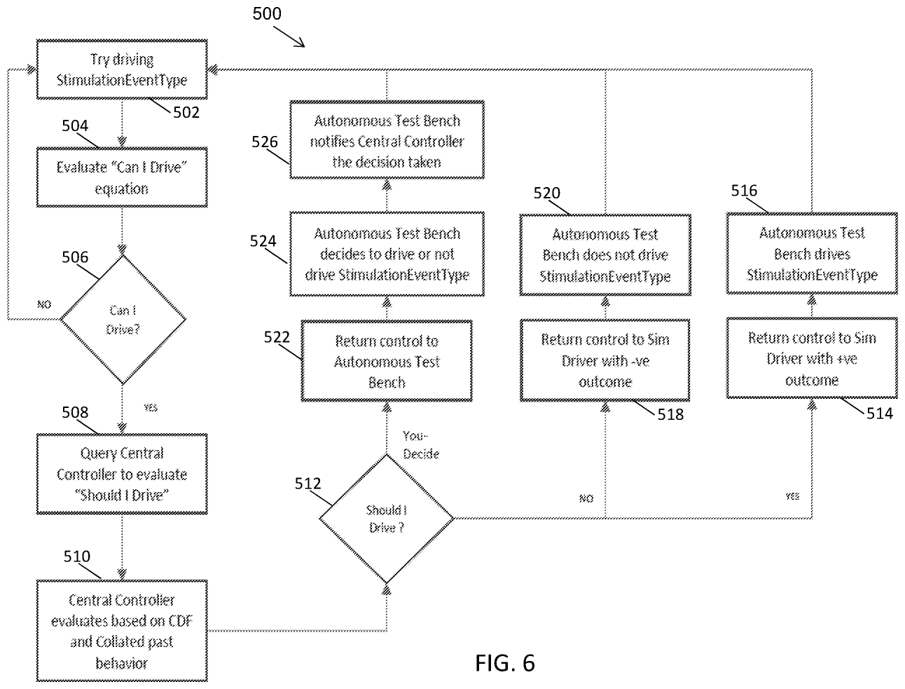

Turning now to FIG. 6, a flow diagram of a process 500 is generally shown in accordance with an embodiment. The process 500 is described with reference to FIGS. 1-5 and may include additional steps beyond those depicted in FIG. 6. The process 500 can be performed by the central controller 202 with respect to the autonomous test benches 204 and DUT 114.

At block 502, an autonomous test bench, such as autonomous test bench 204A, can try driving StimulationEventType 210A. At block 504, the autonomous test bench 204A can evaluate ‘Can I Drive’ logic 206A. At block 506, based on the autonomous test bench 204A evaluating ‘Can I Drive’ logic 206A as ‘No’, then the process 500 returns to block 502. Based on the autonomous test bench 204A evaluating ‘Can I Drive’ logic 206A as ‘Yes’, then the process 500 advances to block 508. At block 508, the autonomous test bench 204A can query the central controller 202 with respect to the ‘Should I Drive’ logic 212. At block 510, the central controller 202 can perform an evaluation based on the CDF 302 and the collate logic 214. At block 512, the ‘Should I Drive’ logic 212 can produce one of a plurality of responses. An affirmative response can result in performing blocks 514 and 516 to drive the StimulationEventType 210A. A negative response can result in performing blocks 518 and 520 to abstain from driving the StimulationEventType 210A. A deferral response (e.g., ‘You-Decide’), the response can result in performing blocks 522, 524, and 526 to return control to the StimulationEventType 210A, decide whether or not to drive the StimulationEventType 210A, and inform the central controller 202 of a decision taken. After blocks 516, 520, and/or 526, the process 500 can return to block 502.

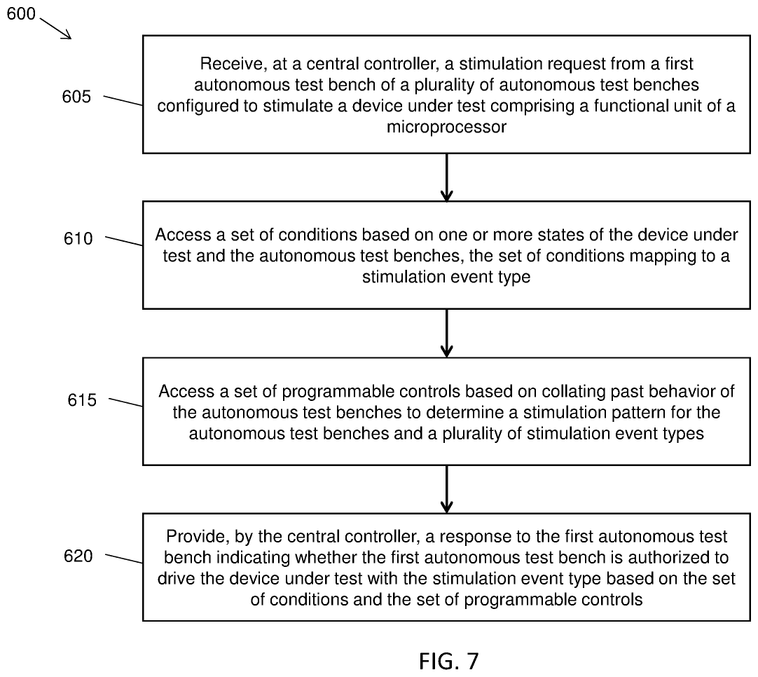

Turning now to FIG. 7, a flow diagram of a process 600 is generally shown in accordance with an embodiment. The process 600 is described with reference to FIGS. 1-6 and may include additional steps beyond those depicted in FIG. 7. The process 600 can be performed by the central controller 202 with respect to the autonomous test benches 204 and DUT 114.

At block 605, central controller 202 can receive a stimulation request from a first autonomous test bench 204A of a plurality of autonomous test benches 204 configured to stimulate a device under test 114 including a functional unit of a microprocessor 100, e.g., functional units 102-112. At block 610, the central controller 202 can access a set of conditions 304A-304D based on one or more states of the device under test 114 and the autonomous test benches 204, where the set of conditions 304A-304D map to a stimulation event type 210. At block 615, the central controller 202 can access a set of programmable controls through collate logic 214 based on collating past behavior of the autonomous test benches 204 to determine a stimulation pattern for the autonomous test benches 204 and a plurality of stimulation event types 210. At block 620, the central controller 202 can provide a response to the first autonomous test bench 204A indicating whether the first autonomous test bench 204A is authorized to drive the device under test 114 with the stimulation event type 210 based on the set of conditions 304A-304D and the set of programmable controls.

In some embodiments, the response to the first autonomous test bench 204A can be an affirmative response indicating that the first autonomous test bench 204A is authorized to drive the device under test 114 with the stimulation event type 210, and the first autonomous test bench 204A drives the device under test 114 with the stimulation event type 210 based on the affirmative response from the ‘Should I Drive’ logic 212 of the central controller 202. The response to the first autonomous test bench 204A can be a negative response indicating that the first autonomous test bench 204A is not authorized to drive the device under test 114 with the stimulation event type 210, and the first autonomous test bench 204A abstains from driving the device under test 114 with the stimulation event type 210 based on the negative response from the ‘Should I Drive’ logic 212 of the central controller 202. The response to the first autonomous test bench 204A can be a deferral response indicating that the first autonomous test bench 204A is authorized to determine whether to drive the device under test 114 with the stimulation event type 210, and the first autonomous test bench 204A can inform the central controller 202 of a decision taken. The first autonomous test bench 204A can be configured to analyze a plurality of conditions to determine a viability of driving the device under test 114 with the stimulation event type 210 based on a set of interface specification rules. Accessing the set of conditions 304A-304D can include accessing a condition definition file 302 that correlates one or more conditions 304A-304D with a specific instance of the stimulation event type 210 or a generic instance of the stimulation event type 210, where the generic instance of the stimulation event type 210 encapsulates two or more of the stimulation event types 210, such as the Generic StimulationEventType 310 encapsulating StimulationEventTypeC 210C and StimulationEventTypeD 210D. The stimulation pattern can define a sequence of two or more of the stimulation event types 210 from one or more of the autonomous test benches 204. Embodiments can include monitoring parallel operation of the autonomous test benches 204 (e.g., by collate logic 214), and updating a record of past behavior of the autonomous test benches 204 to establish a sequence of the stimulation event types 210 applied to the device under test 114 by the autonomous test benches 204 and the one or more states of the device under test 114 as a result of the sequence.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method comprising:
receiving, at a central controller, a stimulation request from a first autonomous test bench of a plurality of autonomous test benches configured to stimulate a device under test comprising a functional unit of a microprocessor;
accessing a set of conditions based on one or more states of the device under test and the autonomous test benches, the set of conditions mapping to a stimulation event type;
accessing a set of programmable controls based on collating past behavior of the autonomous test benches to determine a stimulation pattern for the autonomous test benches and a plurality of stimulation event types; and
providing, by the central controller, a response to the first autonomous test bench indicating whether the first autonomous test bench is authorized to drive the device under test with the stimulation event type based on the set of conditions and the set of programmable controls.

2. The computer-implemented method of claim 1, wherein the response to the first autonomous test bench is an affirmative response indicating that the first autonomous test bench is authorized to drive the device under test with the stimulation event type, and the first autonomous test bench drives the device under test with the stimulation event type based on the affirmative response.

3. The computer-implemented method of claim 1, wherein the response to the first autonomous test bench is a negative response indicating that the first autonomous test bench is not authorized to drive the device under test with the stimulation event type, and the first autonomous test bench abstains from driving the device under test with the stimulation event type based on the negative response.

4. The computer-implemented method of claim 1, wherein the response to the first autonomous test bench is a deferral response indicating that the first autonomous test bench is authorized to determine whether to drive the device under test with the stimulation event type, and the first autonomous test bench informs the central controller of a decision taken.

5. The computer-implemented method of claim 1, wherein the first autonomous test bench is configured to analyze a plurality of conditions to determine a viability of driving the device under test with the stimulation event type based on a set of interface specification rules.

6. The computer-implemented method of claim 1, wherein accessing the set of conditions comprises accessing a condition definition file that correlates one or more conditions with a specific instance of the stimulation event type or a generic instance of the stimulation event type, wherein the generic instance of the stimulation event type encapsulates two or more of the stimulation event types.

7. The computer-implemented method of claim 1, wherein the stimulation pattern defines a sequence of two or more of the stimulation event types from one or more of the autonomous test benches.

8. The computer-implemented method of claim 1, further comprising:
monitoring parallel operation of the autonomous test benches; and
updating a record of past behavior of the autonomous test benches to establish a sequence of the stimulation event types applied to the device under test by the autonomous test benches and the one or more states of the device under test as a result of the sequence.

9. A system comprising:
a device under test comprising a functional unit of a microprocessor;
a plurality of autonomous test benches configured to stimulate the device under test; and
a central controller configured to perform a plurality of operations comprising:
receiving a stimulation request from a first autonomous test bench of the autonomous test benches;
accessing a set of conditions based on one or more states of the device under test and the autonomous test benches, the set of conditions mapping to a stimulation event type;
accessing a set of programmable controls based on collating past behavior of the autonomous test benches to determine a stimulation pattern for the autonomous test benches and a plurality of stimulation event types; and
providing a response to the first autonomous test bench indicating whether the first autonomous test bench is authorized to drive the device under test with the stimulation event type based on the set of conditions and the set of programmable controls.

10. The system of claim 9, wherein the response to the first autonomous test bench is an affirmative response indicating that the first autonomous test bench is authorized to drive the device under test with the stimulation event type, and the first autonomous test bench drives the device under test with the stimulation event type based on the affirmative response.

11. The system of claim 9, wherein the response to the first autonomous test bench is a negative response indicating that the first autonomous test bench is not authorized to drive the device under test with the stimulation event type, and the first autonomous test bench abstains from driving the device under test with the stimulation event type based on the negative response.

12. The system of claim 9, wherein the response to the first autonomous test bench is a deferral response indicating that the first autonomous test bench is authorized to determine whether to drive the device under test with the stimulation event type, and the first autonomous test bench informs the central controller of a decision taken.

13. The system of claim 9, wherein the first autonomous test bench is configured to analyze a plurality of conditions to determine a viability of driving the device under test with the stimulation event type based on a set of interface specification rules.

14. The system of claim 9, wherein accessing the set of conditions comprises accessing a condition definition file that correlates one or more conditions with a specific instance of the stimulation event type or a generic instance of the stimulation event type, wherein the generic instance of the stimulation event type encapsulates two or more of the stimulation event types.

15. The system of claim 9, wherein the stimulation pattern defines a sequence of two or more of the stimulation event types from one or more of the autonomous test benches.

16. The system of claim 9, wherein the central controller is further configured to perform operations comprising:
monitoring parallel operation of the autonomous test benches; and
updating a record of past behavior of the autonomous test benches to establish a sequence of the stimulation event types applied to the device under test by the autonomous test benches and the one or more states of the device under test as a result of the sequence.

17. A computer program product comprising a computer readable storage medium having program instructions embodied therewith, the program instructions executable by a processing system to perform a plurality of operations comprising:
receiving, at a central controller, a stimulation request from a first autonomous test bench of a plurality of autonomous test benches configured to stimulate a device under test comprising a functional unit of a microprocessor;
accessing a set of conditions based on one or more states of the device under test and the autonomous test benches, the set of conditions mapping to a stimulation event type;
accessing a set of programmable controls based on collating past behavior of the autonomous test benches to determine a stimulation pattern for the autonomous test benches and a plurality of stimulation event types; and
providing, by the central controller, a response to the first autonomous test bench indicating whether the first autonomous test bench is authorized to drive the device under test with the stimulation event type based on the set of conditions and the set of programmable controls.

18. The computer program product of claim 17, wherein the response to the first autonomous test bench is an affirmative response indicating that the first autonomous test bench is authorized to drive the device under test with the stimulation event type, and the first autonomous test bench drives the device under test with the stimulation event type based on the affirmative response.

19. The computer program product of claim 17, wherein the response to the first autonomous test bench is a negative response indicating that the first autonomous test bench is not authorized to drive the device under test with the stimulation event type, and the first autonomous test bench abstains from driving the device under test with the stimulation event type based on the negative response.

20. The computer program product of claim 17, wherein the response to the first autonomous test bench is a deferral response indicating that the first autonomous test bench is authorized to determine whether to drive the device under test with the stimulation event type, and the first autonomous test bench informs the central controller of a decision taken.
